(19) United States
(12) Patent Application Publication
(10) Pub. No.: US 2006/0254499 A1
(43) Pub. Date: Nov. 16, 2006

(54) Method For Manufacturing Nitrogen-Doped Silicon Single Crystal

(76) Inventors: Jun Furukawa, Tokyo (JP); Kazuhiro Harada, Tokyo (JP)

Correspondence Address: REED SMITH, LLP;ATTN: PATENT RECORDS DEPARTMENT, 599 LEXINGTON AVENUE, 29TH FLOOR, NEW YORK, NY, 10022-7650, US

(21) Appl. No.: 11/382,121

(22) Filed: May 8, 2006

(30) Foreign Application Priority Data
May 10, 2005 (JP) 2005-136813

(51) Int. Cl. C30B 15/00; C30B 21/06; C30B 27/02; C30B 28/10; C30B 30/04

(52) U.S. Cl. 117/19; 117/20

(57) ABSTRACT

There is provided an improvement in a method for manufacturing a silicon single crystal in which nitrogen is doped at a rate which is not smaller than 1×10¹⁵ atoms/cm³ and less than 4.5×10¹⁵ atoms/cm³ by pulling up a silicon single crystal 29 from a silicon melt 12 which is stored in a quartz crucible 13 and contains nitrogen, wherein the single crystal is pulled up while supplying a silicon raw material 23 which does not contain nitrogen into the silicon melt 12 in such a manner that the liquid level position of the silicon melt stored in the quartz crucible is maintained constant in accordance with the amount of growth of the single crystal. The amount of nitrogen contained in a pulled-up silicon single crystal is controlled, and hence a uniform nitrogen concentration can be obtained along the axial direction of the single crystal. The pull-up length of the silicon single crystal in which nitrogen is doped at a high concentration can be increased.

### BACKGROUND OF THE INVENTION

1. Field of the Invention

The present invention relates to a method for manufacturing a silicon single crystal in which nitrogen is doped based on a Czochralski method (which will be referred to as a CZ method hereinafter).

2. Description of the Related Art

In the CZ method, polycrystal silicon is melted in a crucible formed of amorphous quartz glass, and a seed crystal which has been brought into contact with the upper surface of the silicon melt is pulled up while gently rotating. The silicon melt which contacts the seed crystal loses its heat through the seed crystal and is crystallized with the crystal orientation of the seed crystal when the molten silicon solidifies on the seed crystal, and is pulled up as a silicon single crystal. In the CZ method, therefore, a part of the quartz glass of the crucible which comes into contact with the silicon melt unavoidably melts into the silicon melt, whereby oxygen is blended in the melt. Therefore, the silicon single crystal grown by the CZ method has oxygen as the greatest impurity. 10¹⁷ to 10¹⁸ atoms/cm³ of oxygen are included as an impurity in the silicon single crystal grown by the CZ method.

The impurity oxygen seriously affects mechanical strength, a defect induced by a heat treatment and internal gettering of a silicon wafer obtained by slicing the silicon single crystal. The silicon single crystal grown by the CZ method is mainly used for manufacturing an IC device because of superiority in mechanical strength obtained by this impurity oxygen. This is based on an inherent dislocation securing function of the oxygen. However, a phenomenon occurs in that the silicon single crystal can suddenly become weak against thermal stress when the impurity oxygen has precipitated in the silicon single crystal. A factor causing this phenomenon is that an interstitial oxygen concentration which causes the dislocation securing function is reduced or that an oxygen precipitate serves as a stress concentration source to facilitate occurrence of dislocation.

Furthermore, crystal originated particles (which will be referred to as COPs hereinafter) are also generated on a surface of the wafer cut out from the silicon single crystal. Here, as to the COP, when a mirror-polished silicon wafer is cleaned by using a mixture of ammonia and hydrogen peroxide, a pit is formed on the wafer surface. When this wafer is measured using a particle counter, the pit is also a defect caused due to an original particle as well as a crystal detected as a particle. This COP can be a factor which deteriorates the electrical characteristics, e.g., a time dependent dielectric breakdown (TDDB), a time zero dielectric breakdown (TZDB) and others of an oxide film. Moreover, when the COP exists on the wafer surface, a step is generated in a device wiring process, which can be a factor of disconnection. Additionally, it can cause a leak or the like at an element isolation part, thereby reducing the production yield.

As a method of solving the above-described problems, there is disclosed a method for manufacturing a silicon single crystal by which a nitride is mixed in a polycrystal silicon melt and nitrogen atoms are added in a single crystal (see, e.g., Patent Document 1). According to this method, the occurrence of a crystal defect is sufficiently suppressed in a wafer cut out from the grown silicon single crystal. Further, this wafer has resistance to a thermal stress in a semiconductor element manufacturing process and has a small nitrogen doping amount, and hence it does not affect various electrical characteristics of a semiconductor element.

As methods of doping nitrogen in a silicon single crystal, there are (1) a method which puts polycrystal silicon in which a nitrogen compound is mixed or polycrystal silicon having a silicon nitride film formed thereon into a quartz crucible and pulls up a silicon single crystal from a silicon melt containing nitrogen, (2) a method which grows a single crystal while allowing nitrogen or a nitrogen compound gas to flow into a pull-up furnace, (3) a method which sprays nitrogen or a nitrogen compound gas toward a raw material at a high temperature before melting, (4) a method which uses a crucible formed of a nitride, and others.

Patent Document 1: Japanese Unexamined Patent Application Publication No. S60(1985)-251190 (page 1, lines 5 to 10, and page 3, a right column, lines 2 to 8)

However, in methods (1) and (3), as a silicon melt amount is reduced with growth of the silicon single crystal, the amount of nitrogen contained in the melt also varies. Therefore, there is a problem in that nitrogen cannot be uniformly doped in the grown silicon single crystal. In the case of pulling up the silicon single crystal from the silicon melt containing nitrogen at a predetermined concentration, when the silicon single crystal of 200 mm is pulled upward so that a nitrogen concentration of a crystal top becomes 1×10¹⁵ atoms/cm³, the concentration of nitrogen contained in the silicon single crystal is increased as the solidification ratio becomes high as shown in FIG. 2. Polycrystallization is carried out beyond 4.5×10¹⁵ atoms/cm³ which is the solid solubility limit of nitrogen before the solidification ratio reaches 0.8. Therefore, the pull-up length is determined when manufacturing the silicon single crystal containing nitrogen at a high nitrogen concentration which is substantially 10¹⁵ atoms/cm³. In method (2), it is hard to control the flow quantity of nitrogen or the nitrogen compound gas, and the nitrogen doping amount may possibly increase in the vicinity of the surface of the pulled-up silicon single crystal. In method (4), since the amount of nitrogen which is molten in the melt is increased, silicon nitride (Si₃N₄) is separated out, and this precipitate may fall into the melt to become an impurity.

Furthermore, it is known that nitrogen has a very small segregation coefficient and the concentration of doped nitrogen differs greatly depending on the top portion and the bottom portion of the pulled-up silicon single crystal. Therefore, in the case of pulling up a silicon single crystal in which nitrogen is doped at a high concentration of approximately 1×10 ¹⁵ atoms/cm³ at the top portion, the nitrogen concentration in the silicon single crystal is increased as the pulling-up position comes close to the bottom portion, and dislocation occurs beyond a solid solubility limit of nitrogen. Therefore, there is a problem that the pull-up length with which growth is enabled is limited.

### BRIEF SUMMARY OF THE INVENTION

It is an object of the present invention to provide a method for manufacturing a silicon single crystal, which can control the amount of nitrogen contained in a pulled-up silicon single crystal and the uniformity of the nitrogen concentration along the axial direction of the single crystal.

It is another object of the present invention to provide a method for manufacturing a silicon single crystal, which can increase the pull-up length of the silicon single crystal in which nitrogen is doped at a high concentration.

According to the invention defined in claim 1, as shown in FIG. 1, there is provided an improvement in a method for manufacturing a silicon single crystal obtained by pulling up a silicon single crystal 29 from a silicon melt 12 containing nitrogen stored in a quartz crucible 13 and doping nitrogen at a rate which is not smaller than 1×10¹⁵ atoms/cm³ and less than 4.5×10¹⁵ atoms/cm³, wherein the silicon single crystal is pulled up while supplying a silicon raw material 23 which does not contain nitrogen into the silicon melt 12 in such a manner that the liquid level position of the silicon melt 12 stored in the quartz crucible 13 is maintained constant in accordance with the growth amount of the single crystal.

In the invention defined in claim 1, the silicon single crystal 29 is pulled up while supplying silicon raw material 23 which does not contain nitrogen into the silicon melt 12 containing nitrogen in such a manner that a liquid level position of the silicon melt 12 stored in the quartz crucible 13 is maintained constant in accordance with a growth amount of the single crystal. According to this method, an increase in the nitrogen concentration in the silicon melt 12 due to a segregation phenomenon of nitrogen generated by puling up the single crystal can be suppressed while additionally supplying the silicon raw material 23, thereby growing the silicon single crystal having a uniform nitrogen concentration region in an axial direction.

According to the invention defined in claim 2, there is provided a manufacturing method, wherein the silicon raw material 23 which is supplied and does not contain nitrogen is grained silicon or a silicon melt.

According to the invention defined in claim 3, there is provided an improvement in a method for manufacturing a silicon single crystal obtained by pulling up a silicon single crystal 29 from a silicon melt 12 containing nitrogen stored in a quartz crucible 13 and doping nitrogen at a rate which is not smaller than 1×10¹⁵ atoms/cm³ and less than 4.5×10 ¹⁵ atoms/cm³, and wherein the method comprises the following steps in the order mentioned: pulling up the single crystal 29 while continuously supplying the silicon raw material 23 which does not contain nitrogen into the silicon melt 12 containing nitrogen without moving the quartz crucible 13 up and down in such a manner that the liquid level position of the silicon melt 12 stored in the quartz crucible 13 is maintained constant in accordance with the growth amount of the silicon single crystal 29; and stopping the supply of the silicon raw material 23 and then pulling up the single crystal 29 while moving the quartz crucible 13 up in such a manner that the liquid level position of the silicon melt 12 is maintained constant.

In the invention defined in claim 3, an increase in the nitrogen concentration in the silicon melt 12 due to a segregation phenomenon of nitrogen caused by pulling up the silicon single crystal 29 is suppressed while supplying the silicon raw material 23 into the silicon melt 12, thereby growing a silicon single crystal having a uniform nitrogen concentration region along an axial direction. Additionally, after supply of the silicon raw material is stopped, the silicon single crystal is pulled up by a regular method in succession to the above-described step, and hence the pull-up length of the silicon single crystal in which nitrogen is doped at a high concentration can be greatly increased as compared with the pull-up length of a silicon single crystal according to a prior art.

According to the invention defined in claim 4, in the invention set forth in claim 3, there is provided the manufacturing method, wherein the silicon raw material 23 which is supplied and does not contain nitrogen is grained silicon or a silicon melt.

As described above, according to the present invention, there is provided an improvement in a method for manufacturing a silicon single crystal in which nitrogen is doped at a rate which is not smaller than 1×10¹⁵ atoms/cm³ and less than 4.5×10¹⁵ atoms/cm³ by pulling up the silicon single crystal from a silicon melt containing nitrogen stored in a quartz crucible, wherein the silicon single crystal is pulled up while supplying a silicon raw material which does not contain nitrogen into the silicon melt in such a manner that a liquid level position of the silicon melt stored in the quartz crucible is maintained constant in accordance with the growth amount of the single crystal.

According to this method, an increase in nitrogen concentration in the silicon melt due to a segregation phenomenon of nitrogen caused by pulling up the single crystal can be suppressed while additionally supplying the silicon raw material, thereby growing a silicon single crystal having a uniform nitrogen concentration region in an axial direction.

### BRIEF DESCRIPTION OF THE DRAWINGS

FIG. 1 is a block diagram showing a pull-up apparatus for a silicon single crystal which is used in a manufacturing method according to the present invention; and

FIG. 2 is a view showing a nitrogen concentration and a solidification ratio of a silicon single crystal pulled up from a silicon melt containing nitrogen.

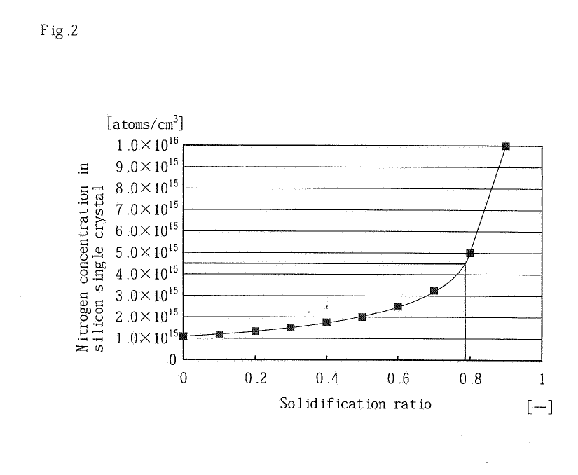

### DETAILED DESCRIPTION OF THE PREFERRED EMBODIMENT

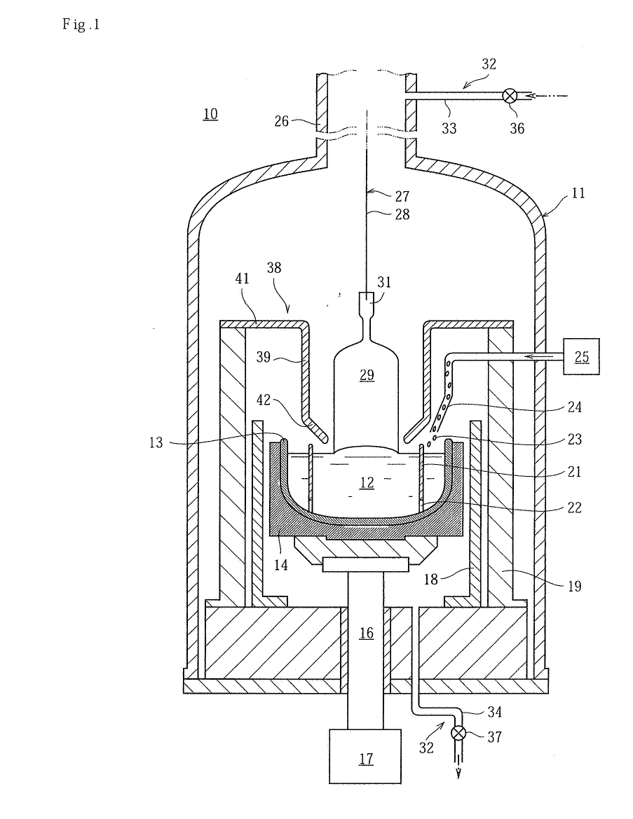

FIG. 1 shows a pull-up apparatus 10 used in a method for manufacturing a silicon single crystal according to the present invention. A quartz crucible 13 which stores a silicon melt 12 therein is provided in a chamber 11 of this pull-up apparatus 10, and an outer peripheral surface of this quartz crucible 13 is covered with a graphite susceptor 14. A lower surface of the quartz crucible 13 is fixed at an upper end of a spindle 16 through the graphite susceptor 14, and a lower portion of this spindle 16 is connected with crucible driving means 17. Although not shown, the crucible driving means 17 has a first rotation motor which rotates the quartz crucible 13 and an elevation motor which moves the quartz crucible 13 up and down. Therefore, the quartz crucible 13 can be rotated in a predetermined direction and moved in a vertical direction by these motors. The outer peripheral surface of the quartz crucible 13 is surrounded by a heater 18 with a predetermined gap therebetween, and this heater 18 is surrounded by a heat-retention cylinder 19. The heater 18 heats/melts a high-purity silicon polycrystal material which is put into the quartz crucible 13 and contains nitrogen, thereby providing a silicon melt 12 containing nitrogen.

A partition ring 21 having substantially the same height as the internal height of the crucible 13 is cylindrically provided in the quartz crucible 13 with a fixed gap between itself and a crucible inner wall surface. A bottom portion of the partition ring 21 is secured on an upper bottom surface of the crucible 13 and configured to partition the inside of the quartz crucible 13 into an inner region at a central part and an outer region at a peripheral part. A communicating portion 22 is formed at a side wall lower portion of the partition ring 21 so that the inner region and the outer region partitioned by the partition ring 21 can communicate with each other through the communicating portion 22. The communicating portion 22 may be, e.g., a hole or a slit piercing the side wall portion, and its shape is not restricted as long as the inner region and the outer region can communicate with each other through this portion. A base end of a supply tube 24 is arranged at a melt upper portion of the outer region with a gap between itself and a melt liquid level. The supply tube 24 pierces the chamber 11, and the other end of the supply tube 24 is connected with storing means 25 provided outside the chamber. A silicon raw material 23 which does not contain nitrogen is stored in the storing means 25. The silicon raw material 23 is configured to be supplied from the outer region of the quartz crucible 13 through the supply tube 24. The silicon raw material 23, may be grained silicon or a silicon melt. This silicon raw material 23 may contain a dopant such as P or B. Incidentally, in case of using the silicon melt as the silicon raw material 23, a non-illustrated small quartz crucible having a heater may be provided above the quart crucible 13 in the chamber 11 without using the supply tube 24 and the storing means 25, the silicon melt may be stored in this small quartz crucible, and the silicon melt may be dropped and supplied into the outer region of the quartz crucible 13.

Furthermore, a cylindrical casing 26 is connected with an upper end of the chamber 11. Pull-up means 27 is provided for this casing 26. The pull-up means 27 has a pull-up head (not shown) horizontally provided at an upper end portion of the casing 26 so as to be capable of turning, a second rotation motor (not shown) which rotates this head, a wire cable 28 which hangs down from the head to the rotation center of the quartz crucible 13, and a pull-up motor (not shown) which is provided in the head and reels the wire cable 28 in or out. A seed crystal 31 which is dipped into the silicon melt 12 to pull up a silicon single crystal ingot 29 is attached at a lower end of the wire cable 28.

Moreover, gas supplying/discharging means 32 which supplies an inert gas from the upper side of the chamber 11 and discharges the inert gas from the lower side of the chamber 11 is connected with the chamber 11. The gas supplying/discharging means 32 has a supply pipe 33 having one end connected with a peripheral wall of the casing 26 and the other end connected with a tank (not shown) which stores the inert gas, and a discharge pipe 34 having one end connected with a lower wall of the chamber 11 and the other end connected to vacuum pump (not shown). First and second flow regulating valves 36 and 37 which adjust the flow quantity of the inert gas flowing through the supply pipe 33 and the discharge pipe 34 are provided for pipes 33 and 34, respectively.

A heat shielding member 38 which surrounds an outer peripheral surface of the ingot 29 is provided between the outer peripheral surface of the ingot 29 and the inner peripheral surface of the quartz crucible 13. This heat shielding member 38 is formed into a cylindrical shape and has a cylindrical portion 39 which prevents radiant heat from the heater 18 and a flange portion 41 which is provided to be continuous with an upper edge of this cylindrical portion 39 and bulge in a substantially horizontal direction. When the flange portion 41 is mounted on the heat-retention cylinder 19, the heat shielding member 38 is fixed in the chamber 11 in such a manner that a lower edge of the cylindrical portion 39 is positioned above the surface of the silicon melt 12 with a predetermined distance therebetween. The cylindrical portion 39 in this embodiment is a cylindrical body having the same diameter, and a bulge portion 42 which bulges in the direction of the inside of the cylinder is provided at a lower part of this cylindrical portion 39. Each of the cylindrical portion 39 and the bulge portion 42 is formed of C (graphite), graphite having SiC coated on a surface thereof, or the like.

A manufacturing method using the thus configured manufacturing apparatus of a silicon single crystal will now be described.

According to the method for manufacturing a silicon single crystal of the present invention, the seed crystal 31 is dipped in an inner region of the silicon melt 12 which is stored in the quartz crucible 13 and contains nitride, and the seed crystal 31 is pulled upward at a predetermined speed, thereby manufacturing the silicon single crystal 29 in which nitrogen is doped at a rate which is not smaller than 1×10¹⁵ atoms/cm³ and less than 4.5×10¹⁵ atoms/cm³. A characteristic structure of the present invention lies in that the single crystal 29 is pulled upward while supplying the silicon raw material 23 which does not contain nitrogen into the silicon melt 12 containing nitrogen in such a manner that the liquid level position of the silicon melt 12 stored in the quartz crucible 13 is maintained constant in accordance with the growth amount of the single crystal. Based on this method, an increase in nitrogen concentration in the silicon melt 12 due to a segregation phenomenon of nitrogen caused by pulling up the single crystal can be suppressed while additionally supplying the silicon raw material 23, thereby growing a silicon single crystal having a uniform nitrogen concentration region in an axial direction.

The concentration of nitrogen contained in the silicon single crystal to be pulled up and the concentration of nitrogen contained in the silicon melt have a relationship represented by the following Expression (1) under given fixed conditions:
[C]ₛ=k₀[C]₀(1−L)^{k0-1} (1)

In Expression (1), [C]ₛ is a concentration of nitrogen in the crystal, [C]₀ is an initial concentration of nitrogen in the silicon melt, k₀ is a segregation coefficient, and the segregation coefficient of nitrogen is 7×10⁻⁴, and L is a solidification ratio.

Since the solidification ratio L in Expression (1) is zero immediately after the silicon single crystal is pulled up, a nitrogen concentration of 1×10¹⁵ atoms/cm³ at the top portion of the silicon single crystal can be achieved by controlling the nitrogen concentration in the silicon melt to approximately 1.43×10¹⁸ atoms/cm³. It is to be noted that the silicon single crystal in which the concentration of nitrogen in the top portion does not reach 1×10¹⁵ atoms/cm³ immediately after the upward pulling operation is formed if the concentration of nitrogen contained in the silicon melt is less than 1.43×10¹⁸ atoms/cm³. As methods of allowing nitrogen to be contained in the silicon melt, there are (1) the above-described method of putting polycrystal silicon in which a nitrogen compound is mixed or polycrystal silicon having a silicon nitride film formed thereon into the quartz crucible and pulling up the silicon single crystal from the silicon melt containing nitrogen, (2) a method of spraying nitrogen or a nitrogen gas compound to a raw material at a high temperature before melting, and others. However, the present invention is not restricted to these methods.

It is preferable for the method for manufacturing a nitrogen-doped silicon single crystal according to the present invention to include a step of pulling up the single crystal 29 while continuously supplying the silicon raw material 23 which does not contain nitrogen into the silicon melt 12 containing nitrogen without moving the quartz crucible 13 up and down in such a manner that the liquid level position of the silicon melt 12 stored in the quartz crucible 13 is maintained constant in accordance with the amount of growth of the silicon single crystal, and a step of pulling up the single crystal 29 while moving the quartz crucible 13 up in such a manner that the liquid level position of the silicon melt 12 is maintained constant after stopping supply of the silicon raw material 23 in the mentioned order. According to the above-described method, since an increase in concentration of nitrogen in the silicon melt 12 due to a segregation phenomenon of nitrogen caused by pulling up the silicon single crystal 29 is suppressed while supplying the silicon raw material 23 into the silicon melt 12, the silicon single crystal having a uniform nitrogen concentration region in an axial direction can be grown. Further, after supply of the silicon raw material 23 is stopped, the silicon single crystal is pulled up by the regular method in succession to the above-mentioned steps. Therefore, the pull-up length of the silicon single crystal in which nitrogen is doped at a high concentration can be greatly increased as compared with the pull-up length of the silicon single crystal which is pulled up by the conventional method.

### EXAMPLE

An example according to the present invention as well as a comparative example will now be described in detail.

### Example 1

80 kg of a silicon melt containing nitrogen at a rate of 1.43×10¹⁵ atoms/cm³ was stored in a quartz crucible. Furthermore, 80 kg of a silicon raw material which does not contain nitrogen was prepared. Then, a seed crystal was dipped in the silicon melt, and this seed crystal was pulled upward while gently rotating to start growth of a silicon single crystal having a diameter of 8 inches (approximately 200 mm). The silicon raw material which does not contain nitrogen was continuously supplied into the silicon melt without moving the quartz crucible up and down in such a manner that the liquid level position of the silicon melt stored in the quartz crucible is maintained constant in accordance with the amount of growth of the single crystal until 80 kg of the silicon single crystal is grown. Subsequently, after stopping supply of the silicon raw material, the silicon single crystal was grown while moving the quartz crucible up in such a manner that the liquid level position of the silicon melt is maintained constant, and the upward pulling operation was stopped when 4.5×10¹⁵ atoms/cm³ which is the solid solubility limit of nitrogen was achieved.

### Comparative Example 1

160 kg of a silicon melt which contains nitrogen at a rate of 1.43×10¹⁵ atoms/cm³ was stored in a quartz crucible. A seed crystal was dipped in the silicon melt, and this seed crystal was pulled upward while gently rotating to start growth of a silicon single crystal having a diameter of 8 inches (approximately 200 mm). The silicon single crystal was grown while moving the quartz crucible up in such a manner that the liquid level position of the silicon melt is maintained constant, and the upward pulling operation was stopped when 4.5×10¹⁵ atoms/cm³ which is the solid solubility limit of nitrogen was achieved.

<Comparative Test 1>

In the method of Comparative Example 1, 4.5×10¹⁵ atoms/cm³ which is the solid solubility limit of nitrogen was achieved in the vicinity of 1650 mm as a pull-up length to perform polycrystallization. The solidification ratio L of the silicon single crystal with respect to the silicon melt used in the example was 0.78. In upward pulling of the silicon single crystal based on the CZ method, a neck portion and a shoulder portion are formed, and then a base portion which is utilized as a product is formed. Therefore, approximately 1550 to 1600 mm excluding the neck portion and the shoulder portion in an entire pull-up length is grown as the base portion.

On the other hand, in the method of Example 1, 4.5×10¹⁵ atoms/cm³ which is the solid solubility limit of nitrogen was achieved in the vicinity of 1900 mm as a pull-up length to perform polycrystallization. The solidification ratio L of the silicon single crystal with respect to the silicon melt and the silicon raw material used in the example was 0.89. Therefore, approximately 1800 to 1850 mm excluding the neck portion and the shoulder portion in an entire pull-up length was grown as the base portion. Furthermore, in the method of Example 1, in a region grown as the base portion, approximately 1100 mm as a crystal length was provided as a uniform nitrogen concentration region of approximately 1×10¹⁵ atoms/cm³. Moreover, in the method of Example 1, the amount of nitrogen added to the silicon melt stored in the quartz crucible before upward pulling was reduced to approximately ½ as compared with Comparative Example 1.

What is claimed is:

1. A method for manufacturing a nitrogen-doped silicon single crystal in which nitrogen is doped at a rate which is not smaller than 1×10¹⁵ atoms/cm³ and less than 4.5×10¹⁵ atoms/cm³ by pulling up a silicon single crystal (29) from a silicon melt (12) which is stored in a quartz crucible (13) and contains nitrogen, comprising the step of:
pulling up the single crystal (29) while supplying a silicon raw material (23) which does not contain nitrogen into the silicon melt (12) in such a manner that the liquid level position of the silicon melt (12) stored in the quartz crucible (13) is maintained constant in accordance with the amount of growth of the single crystal.

2. The method according to claim 1, wherein the supplied silicon raw material (23) which does not contain nitrogen is grained silicon or a silicon melt.

3. A method for manufacturing a nitrogen-doped silicon single crystal in which nitrogen is doped at a rate which is not smaller than 1×10¹⁵ atoms/cm³ and less than 4.5×10¹⁵ atoms/cm³ by pulling up a silicon single crystal (29) from a silicon melt (12) Which is stored in a quartz crucible (13) and contains nitrogen, comprising in this order, order the steps of:
pulling up the single crystal (29) while continuously supplying the silicon raw material (23) which does not contain nitrogen into the silicon melt (12) containing nitrogen without moving up and down the quartz crucible (13) in such a manner that the liquid level position of the silicon melt (12) stored in the quartz crucible (13) is maintained constant in accordance with the amount of growth of the silicon single crystal (29); and
pulling the single crystal (29) up while moving the quartz crucible (13) up in such a manner that the liquid level position of the silicon melt (12) is maintained constant after stopping supply of the silicon raw material (23).

4. The method according to claim 3, wherein the supplied silicon raw material (23) which does not contain nitrogen is grained silicon or a silicon melt.

5. A nitrogen-doped silicon single crystal prepared by the method of claim 1.

6. A nitrogen-doped silicon single crystal prepared by the method of claim 2.

7. A nitrogen-doped silicon single crystal prepared by the method of claim 3.

8. A nitrogen-doped silicon single crystal prepared by the method of claim 4.

9. A silicon wafer made from the nitrogen-doped silicon single crystal of claim 5.

10. An IC device made from the wafer of claim 9.
